(19) United States
(12) Patent Application Publication
(10) Pub. No.: US 2010/0007008 A1
(43) Pub. Date: Jan. 14, 2010

(54) BGA PACKAGE

(76) Inventor: AKIHIRO SANO, Kanagawa (JP)

Correspondence Address: Mr. Jackson Chen, 6535 N. STATE HWY 161, IRVING, TX, 75039, US

(21) Appl. No.: 12/498,137

(22) Filed: Jul. 6, 2009

(30) Foreign Application Priority Data
Jul. 9, 2008 (JP) 2008-179416

(51) Int. Cl. H01L 23/498

(52) U.S. Cl. 257/692; 257/E23.069

(57) ABSTRACT

A BGA package has an LSI package, a plurality of terminal pads arranged in a grid pattern on the rear surface of the LSI package, and solder balls for soldering the LSI package to a printed wiring board via the terminal pads. A plurality of the terminals pads located at each of the four corners of the outermost periphery of the LSI package form a group of first terminal pads, and each group of terminal pads is formed integrally as a reinforcing pad having a greater size than that of the other terminal pads.

This application is based upon and claims the benefit of priority from Japanese patent application No. 2008-179416, filed on Jul. 9, 2008, the disclosure of which is incorporated herein in its entirety by reference.

### FIELD OF THE INVENTION

This invention relates to a BGA (ball grid array) package and, in particular, to a BGA package for preventing peeling of terminal pads.

### DESCRIPTION OF THE RELATED ART

Some devices having a multiplicity of terminals like a conventional small-sized BGA suffer breakdowns due to peeling of square terminal pads possibly caused by the devices being dropped or subjected to a shock.

Even though a device apparently does not seem damaged significantly, it may be severely damaged in the inside thereof. It is very difficult in practice to determine for an LSI in a BGA package whether and how it is damaged.

Techniques relating to this are described for example in Japanese Laid-Open Patent Publication No. 2001-244585 (Patent Document 1), No. 2005-191041 (Patent Document 2), and No. 2006-165088 (Patent Document 3).

Patent Document 1 relates to a printed circuit board or printed wiring board (PWB) having pads for positioning BGA components (including LCAs) on a printed wiring board (PWB).

Patent Document 2 principally relates to a pattern layout on a printed wiring board (PWB). All the pattern pads on the printed wiring board in a BGA component are reinforced by being laid out at an angle of 45 degrees to respective through holes.

Patent Document 3 relates to a BGA package in which land portions (pin pattern pads) on the outermost periphery of the BGA package are greater than inner ones. Specifically, land portions (pin pattern pads) for pins at the four corners and three pins adjacent to the four corners on the outermost periphery are formed greater than the inner ones.

### SUMMARY OF THE INVENTION

This invention has been made in order to solve problems associated with the related arts described above, and it is an object of this invention to provide a BGA package capable of reducing failures and breakdowns caused by peeling of terminal pads.

In order to achieve the object above, the invention provides a BGA package having an LSI package, a plurality of first terminal pads arranged in a grid pattern on the rear surface of the LSI package, and solder balls for soldering the LSI package to a printed wiring board via the first terminal pads, wherein a plurality of the first terminals pads located at each of the four corners of the outermost periphery of the LSI package form a group of first terminal pads, and each group of first terminal pads is formed integrally as a first reinforcing pad having a greater size than that of the other first terminal pads.

### BRIEF DESCRIPTION OF THE DRAWINGS

FIG. 1 is a diagram showing a known BGA package as viewed from below;

FIG. 2 is a diagram also showing the known BGA package as viewed from below;

FIG. 3 is a diagram showing the known BGA package mounted on a printed wiring board as viewed from a side;

FIG. 4 is a diagram showing a BGA package according to an embodiment of this invention as viewed from below; and

FIG. 5 is a diagram showing the BGA package mounted on a printed wiring board according to an embodiment of this invention, as viewed from a side.

### DESCRIPTION OF PREFERRED EXEMPLARY EMBODIMENTS

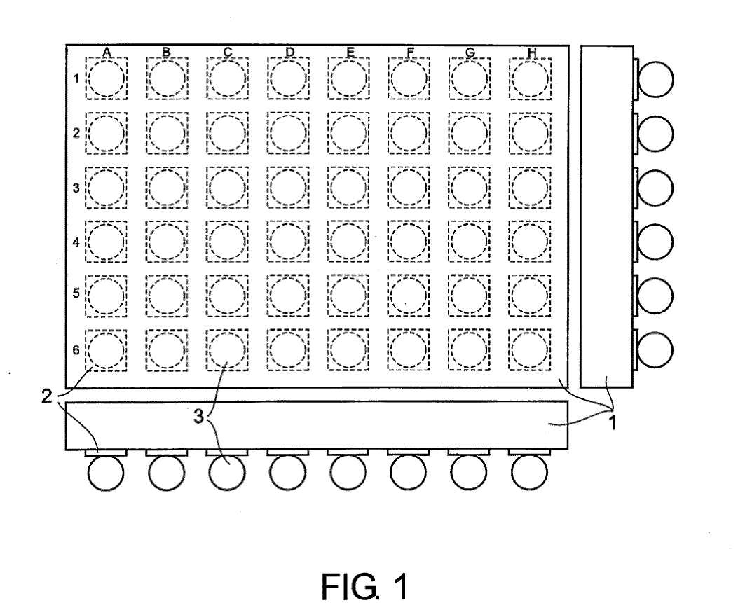

First, a known type of BGA package will be described with reference to FIG. 1 to FIG. 3.

As shown in FIGS. 1 to 3, this known BGA package has an LSI package 1, a plurality of terminal pads 2 arranged in a grid pattern on the rear surface of the LSI package 1, and solder balls 3 for soldering the LSI package 1 to terminal pads 5 on a printed wiring board 4 via the terminal pads 2.

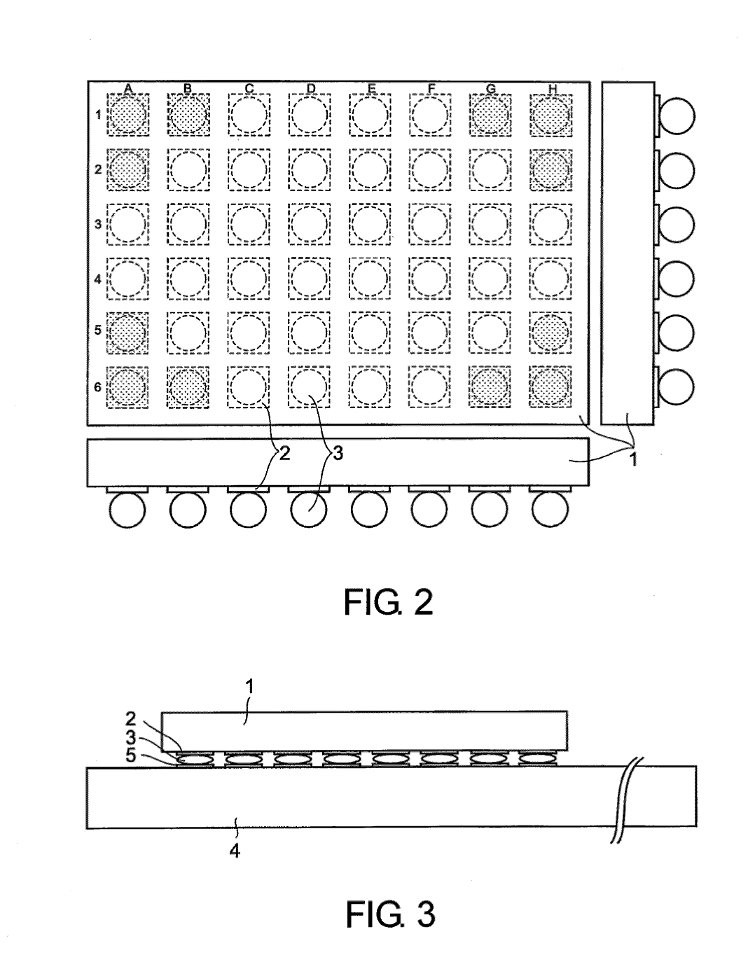

Among the terminal pads 2 of the known BGA package, those terminal pads at the four corners (three pads at each of the corners) are weak and prone to peeling. FIG. 2 shows the terminal pads at the four corners which are possibly broken. Specifically, three terminal pads 2 arranged at the positions 1-A, 1-B, 2-A at the upper left corner of the grid-like layout, three terminal pads 2 at the positions 5-A, 6-A, 6-B at the lower left corner, three terminal pads 2 at the positions 1-G, 1-H, 2-H at the upper right corner, and three terminal pads 2 at the positions 5-H, 6-G, 6-H at the lower right corner are those terminal pads which are prone to peeling.

The recent trend of miniaturization of devices (terminal devices) increases the degree of circuit integration and the number of LSI terminals. Under such circumstances, the area of the BGA package itself becomes smaller and, thus, the area of the terminal pads also becomes smaller. As a result, the adhesive force of each terminal pad is decreased.

As for those terminal pads for use in a small-sized and portable terminal, in particular, serious problems such as failures and breakdowns of the device are entailed if the terminals pads are peeled off as a result of deformation of a printed wiring board caused by the device being dropped or being subjected to a shock.

Various countermeasures are taken against this problem, including reinforcement with the use of an adhesive agent, and a design in which terminal pads at the four corners are not used on the assumption that the number of usable pins is reduced. However, these countermeasures cause the prices of the devices to rise.

This invention has been made in view of the problems encountered in the conventional techniques as described above, and it is an object of the invention to provide a BGA package capable of reducing failures and breakdowns caused by peeling of terminal pads.

An exemplary preferred embodiment of this invention will be described in detail with reference to the accompanying drawings.

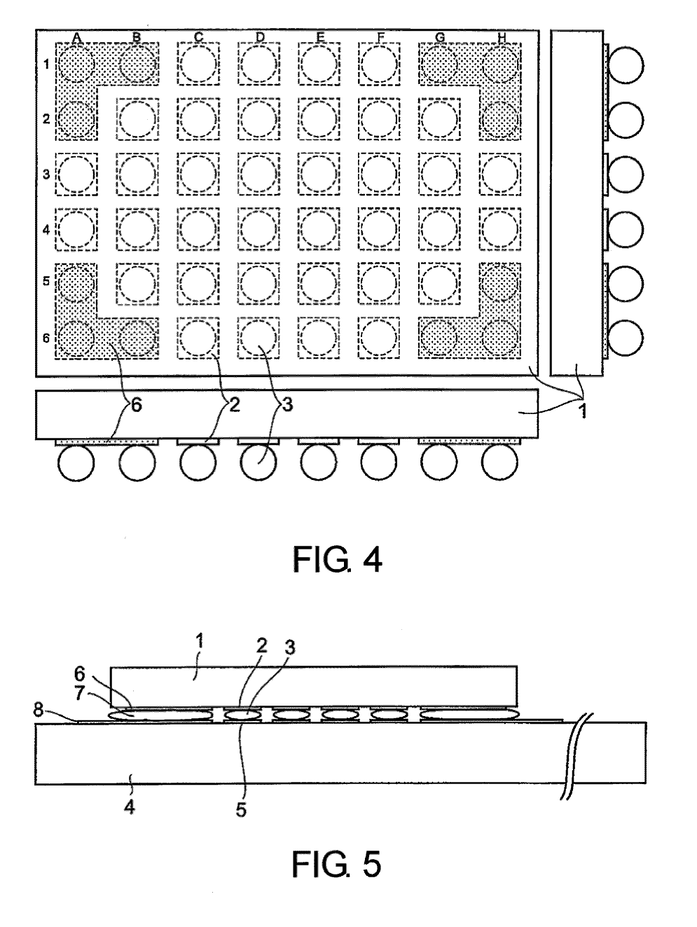

A BGA package according to an exemplary embodiment of this invention will be described with reference to FIGS. 4 and 5. Here, for convenience of description, the same parts and components as those shown in FIGS. 1 to 3 are assigned with the same reference numerals.

FIG. 4 is a diagram showing a BGA package as viewed from below.

Referring to FIG. 4, the BGA package has an LSI package (body) 1, terminal pads 2 serving as terminals of the LSI package, solder balls 3 for soldering the LSI package 1 to a printed wiring board 4 (see FIG. 5), and reinforcing pads 6.

FIG. 5 is a diagram showing the BGA package mounted on the printed wiring board, as viewed from a side.

Referring to FIG. 5, the terminal pads 2 and reinforcing pads 6 of the LSI package 1 are bonded to improving and reinforcing pads 8 and terminal pads 5 on the printed wiring board 4 by thermal welding with solder balls 3, 7.

As shown in FIG. 4, a plurality of the terminal pads 2 are arranged in a grid pattern on the rear surface of the LSI package 1. A plurality of terminals pads located at each of the four corners of the outermost periphery of the LSI package 1 form a group of terminal pads, and each group of terminal pads is formed as an integral reinforcing pad 6 having a greater size than that of the other terminal pads 2. Specifically, three terminal pads 2 located at each of the four corners of the outermost periphery of the LSI package 1 are formed integrally as a reinforcing pad 6 having an L-shaped pattern.

More specifically, three terminal pads 2 located at the positions 1-A, 1-B, 2-A at the upper left corner of the grid-like layout, three terminal pads 2 located at the positions 5-A, 6-A, 6-B at the lower left corner, three terminal pads 2 located at the positions 1-G, 1-H, 2-H at the upper right corner, and three terminal pads 2 located at the positions at the lower right corner 5-H, 6-G, 6-H are formed integrally as reinforcing pads 6 having an L-shaped pattern.

A plurality of terminal pads 5 are arranged in a grid pattern also on the top surface of the printed wiring board 4. These terminal pads 5 are respectively connected to the plurality of terminal pads 2 likewise arranged in a grid pattern on the rear surface of the LSI package 1 via the solder balls 3.

A plurality of terminals pads located at each of the four corners of the outermost periphery of the printed wiring board 4 form a group of terminal pads, and each group of terminal pads is formed as an integral improving and reinforcing pad 8 having a greater size than that of the other terminal pads 5.

After being configured as described above, the reinforcing pads 6 arranged on the rear surface of the LSI package 1 are connected to the improving and reinforcing pads 8 arranged on the top surface of the printed wiring board 4 by means of solder balls 7 having a greater size than that of the solder balls 3. For example, the reinforcing pads 6 and the improving and reinforcing pads 8 are mutually connected by thermal welding with the use of the solder balls 7.

The BGA package according to this embodiment of the invention, configured as described above, is enabled to have a greater mounting area than (at least more than double) the size of conventional BGA packages (see FIGS. 1 to 3), whereby the adhesive force can be enhanced.

The above embodiment of the invention makes it possible to reduce the failures and breakdowns caused by peeling of the terminal pads. Further, the embodiment of the invention, in which the LSI package is reinforced at the four corners on the outermost periphery thereof, makes it possible to omit other reinforcement means such as the use of an adhesive agent. This makes it possible to reduce the man-hours required to manufacture the BGA package, and hence to reduce the manufacturing cost.

The embodiment of this invention allows the heat-generating LSI to have a heat dissipation effect depending on the pattern layout of the printed wiring board 4. If the amount of generated heat is not significant, a sufficient heat dissipation effect can be achieved by connecting the improving and reinforcing pads 8 on the printed wiring board 4 to the ground or the like without the need of adding extra fins or the like.

As described above, the embodiment of the invention makes it possible to prevent the breakdowns and to reduce the failure rate of the device, by the layout for reinforcing and preventing the peeling of the pads (of the pattern connected to the printed wiring board) connected to the terminals at the four corners of the known BGA package (see FIGS. 1 to 3).

In the BGA package according to the above embodiment of this invention, the terminal pads, which have been conventionally not used, are formed to have a greater area to increase their adhesive force. The terminal pads at the four corners of the LSI package are used as reinforcing pads. The adhesive force is thus enhanced and the failure of the device (terminal device) can thereby be prevented.

According to this invention, the failures and breakdowns caused by peeling of the terminal pads can be reduced. Further, according to this invention, the four corners of the outermost periphery of the LSI package are reinforced, whereby the need of reinforcement with the use of an adhesive agent or the like can be eliminated. This reduces the man-hours required to manufacture, and hence to reduce the manufacturing cost.

It should be understood that although the invention made by this inventor has been described specifically on the basis of its preferred embodiment, this invention is not limited to the embodiment described above, but various other modifications and variations are possible without departing from the scope and spirit of the invention.

For example, while three terminal pads 2 are arranged at each of the four corners of the outermost periphery of the LSI package 1 in FIG. 4, the number of the terminal pads 2 is not limited to three but may be a number greater than three.

What is claimed is:

1. A BGA package comprising:
an LSI package;
a plurality of first terminal pads arranged in a grid pattern on a rear surface of the LSI package; and
solder balls for soldering the LSI package to a printed wiring board via the first terminal pads,
wherein a plurality of the first terminals pads located at each of the four corners of an outermost periphery of the LSI package form a group of first terminal pads, each group of first terminal pads being formed integrally as a first reinforcing pad having a greater size than a size of the other first terminal pads.

2. The BGA package as claimed in claim 1, wherein at least three first terminal pads are arranged at each of the four corners of the outermost periphery of the LSI package, and each of the first reinforcing pads is integrally formed in an L-shaped pattern.

3. The BGA package as claimed in claim 1, wherein a plurality of second terminal pads are arranged in a grid pattern on a top surface of the printed wiring board, and the second terminal pads are connected to the first terminal pads via the solder balls.

4. The BGA package as claimed in claim 1, wherein a plurality of the second terminals pads located at each of the four corners of an outermost periphery of the printed wiring board form a group of second terminal pads, each group of second terminal pads being formed integrally as a second reinforcing pad having a greater size than a size of the other second terminal pads.

5. The BGA package as claimed in claim 1, wherein the first reinforcing pads and the second reinforcing pads are mutually connected via solder balls having a greater size than a size of the solder balls for connecting the first and second terminal pads.

6. The BGA package as claimed in claim 5, wherein the first reinforcing pads and the second reinforcing pads are mutually connected by thermal welding using the solder balls having the greater size than the size of the solder balls for connecting the first and second terminal pads.

7. The BGA package as claimed in claim 4, wherein the second reinforcing pads are connected to a ground.
